(19) United States
(12) Patent Application Publication
(10) Pub. No.: US 2011/0193188 A1
(43) Pub. Date: Aug. 11, 2011

(54) IMAGE SENSOR

(75) Inventor: Shu-Fang Wang, Hsinchu City (TW)

(73) Assignee: NOVATEK MICROELECTRONICS CORP., Hsinchu (TW)

(21) Appl. No.: 12/838,703

(22) Filed: Jul. 19, 2010

(30) Foreign Application Priority Data
Feb. 9, 2010 (TW) 099104016

(51) Int. Cl. H01L 31/0216; H01L 31/0232

(52) U.S. Cl. 257/432; 257/435; 257/E31.122; 257/E31.127

(57) ABSTRACT

An image sensor comprising a black pixel region and an active pixel region is provided. The active pixel region is adjacent to the black pixel region. The black pixel region comprises a dummy black pixel region and a readout black pixel region. The readout black pixel region is surrounded by the dummy black pixel region. The dummy black pixel region comprises a photo-sensitive element, a first shielding layer, a second shielding layer and a third shielding layer. The first shielding layer, the second shielding layer and the third shielding layer are used for blocking the incident light going into the photo-sensitive element. The first shielding layer, the second shielding layer and the third shielding layer cover the photo-sensitive element, and the second shielding layer is interposed between the first shielding layer and the third shielding layer.

This application claims the benefit of Taiwan application Serial No. 99104016, filed Feb. 9, 2010, the subject matter of which is incorporated herein by reference.

### BACKGROUND OF THE INVENTION

1. Field of the Invention

The invention relates in general to an image sensor, and more particularly to an image sensor which reduces the size of the black pixel region.

2. Description of the Related Art

Referring to FIG. 1, a conventional image sensor is shown. The conventional image sensor 10 comprises an active pixel region 11 and a black pixel region 14. The black pixel region 14 comprises an upper black pixel region 12 and a left black pixel region 13. The upper black pixel region 12 is used for obtaining a frame dark level, and the left black pixel region 13 is used for obtaining a row dark level. The conventional image sensor 10 uses the dark level as the lowest level. The brightness of the active pixel region 11 is calculated from the black level of the active pixel in the active pixel region 11. If the black level is too high, the image dynamic range will be reduced or even the low brightness of the image will be affected.

Referring to FIG. 2, a 4×4 pixel array of a conventional image sensor is shown. For purpose of simplification, FIG. 2 is exemplified by a 4×4 pixel array which comprises 16 photo-sensitive elements PD realized by such as photodiodes. The pixel array of FIG. 2 comprises a 2×2 pixel array 122 located in the black pixel region 14.

Referring to FIG. 3 and FIG. 4. FIG. 3 shows a cross-sectional view along the cross-sectional line A-A′ of FIG. 2. FIG. 4 shows a cross-sectional view along the cross-sectional line B-B′ of FIG. 2. The layout structure of the active pixel region 11 is similar to that of the black pixel region 14 except that the active pixel region 11 lacks a shielding layer 23 of the black pixel region 14. The shielding layer 23 is realized by such as metal or metal and blue color filter.

When the incident light L is vertically radiated on the pixel array, the shielding layer 23 of the black pixel region 14 reflects the incident light L to avoid the incident light L going into the photodiode PD of the black pixel region 14. Since the active pixel region 11 lacks the shielding layer 23, the incident light L goes into the photodiode PD of the active pixel region 11.

Referring to FIG. 5 and FIG. 6. FIG. 5 shows an incident light being slantedly radiated on the black pixel region along a direction. FIG. 6 shows an incident light being slantedly radiated on the black pixel region along another direction. When the incident light L is slantedly radiated on the black pixel region 14, a part of the incident light L goes into the photodiode PD of the black pixel region 14. The current practice avoids the photodiode PD of the black pixel region 14 being radiated by the incident light L by increasing the size of the black pixel region 14. However, when the black pixel region 14 increases, the size of the image sensor will increase accordingly.

### SUMMARY OF THE INVENTION

The invention is directed to an image sensor which reduces its size through the design of a dummy black pixel region.

According to a first aspect of the present invention, an image sensor comprising a black pixel region and an active pixel region is provided. The active pixel region is adjacent to the black pixel region. The black pixel region comprises a dummy black pixel region and a readout black pixel region. The readout black pixel region is surrounded by the dummy black pixel region. The dummy black pixel region comprises a photo-sensitive element, a first shielding layer, a second shielding layer and a third shielding layer. The first shielding layer, the second shielding layer and the third shielding layer are used for blocking the incident light going into the photo-sensitive element. The first shielding layer, the second shielding layer and the third shielding layer cover the photo-sensitive element, and the second shielding layer is interposed between the first shielding layer and the third shielding layer.

The invention will become apparent from the following detailed description of the preferred but non-limiting embodiments. The following description is made with reference to the accompanying drawings.

### BRIEF DESCRIPTION OF THE DRAWINGS

FIG. 1 shows a conventional image sensor;

FIG. 2 shows a 4×4 pixel array of a conventional image sensor;

FIG. 3 shows a cross-sectional view along the cross-sectional line A-A′ of FIG. 2;

FIG. 4 shows a cross-sectional view along the cross-sectional line B-B′ of FIG. 2;

FIG. 5 shows an incident light being slantedly radiated on the black pixel region along a direction;

FIG. 6 shows an incident light being slantedly radiated on the black pixel region along another direction;

FIG. 7 shows an image sensor according to a preferred embodiment of the invention;

FIG. 8 shows an 4×4 pixel array according to a preferred embodiment of the invention;

FIG. 9 shows a cross-sectional view along the cross-sectional line A-A′ of FIG. 8;

FIG. 10 shows a cross-sectional view along the cross-sectional line B-B′ of FIG. 8;

FIG. 11 shows an incident light being slantedly radiated on the dummy black pixel region along a direction; and

FIG. 12 shows an incident light being slantedly radiated on the dummy black pixel region along another direction.

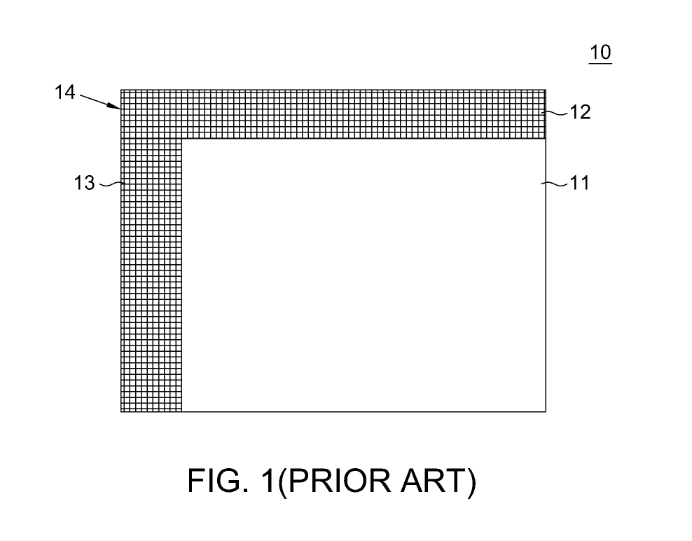

### DETAILED DESCRIPTION OF THE INVENTION

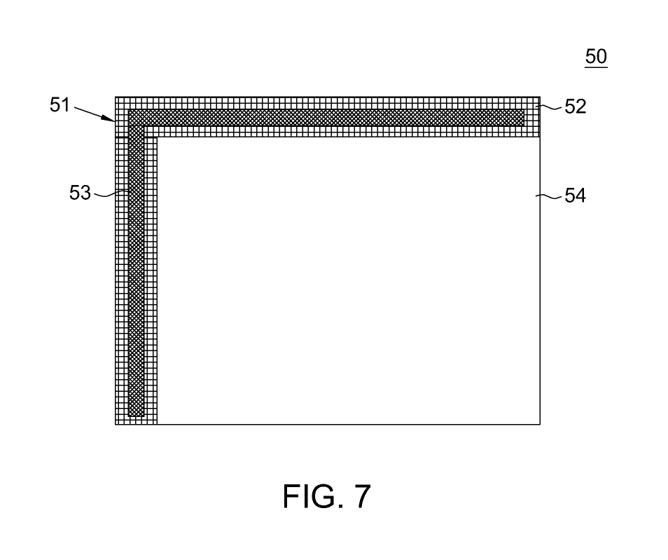

Referring to FIG. 7, an image sensor according to a preferred embodiment of the invention is shown. The image sensor 50 comprises an active pixel region 54 and a black pixel region 51, wherein the active pixel region 54 is adjacent to the black pixel region 51. The black pixel region 51 comprises a dummy black pixel region 52 and a readout black pixel region 53, wherein the readout black pixel region 53 is surrounded by the dummy black pixel region 52.

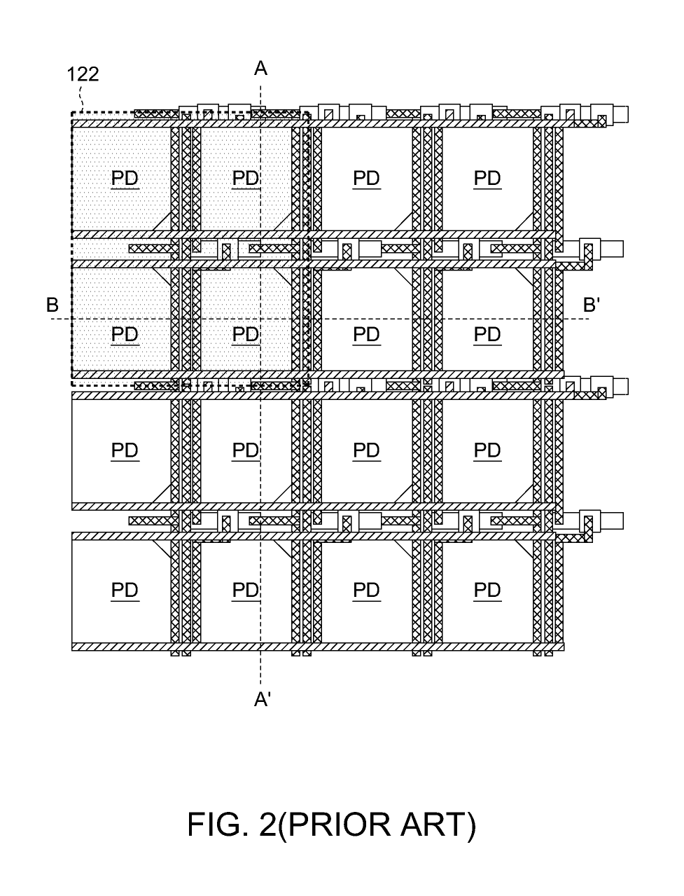

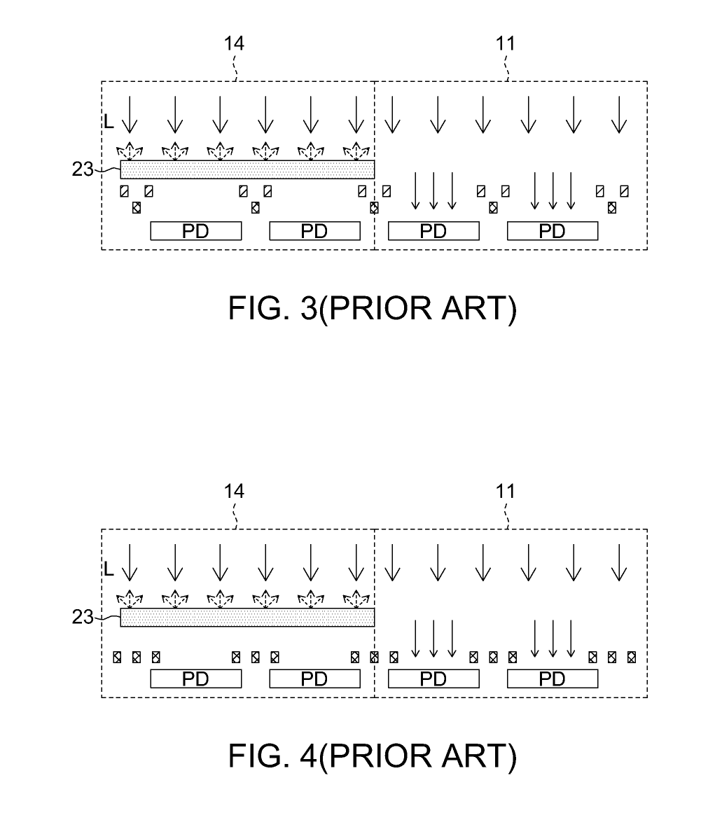

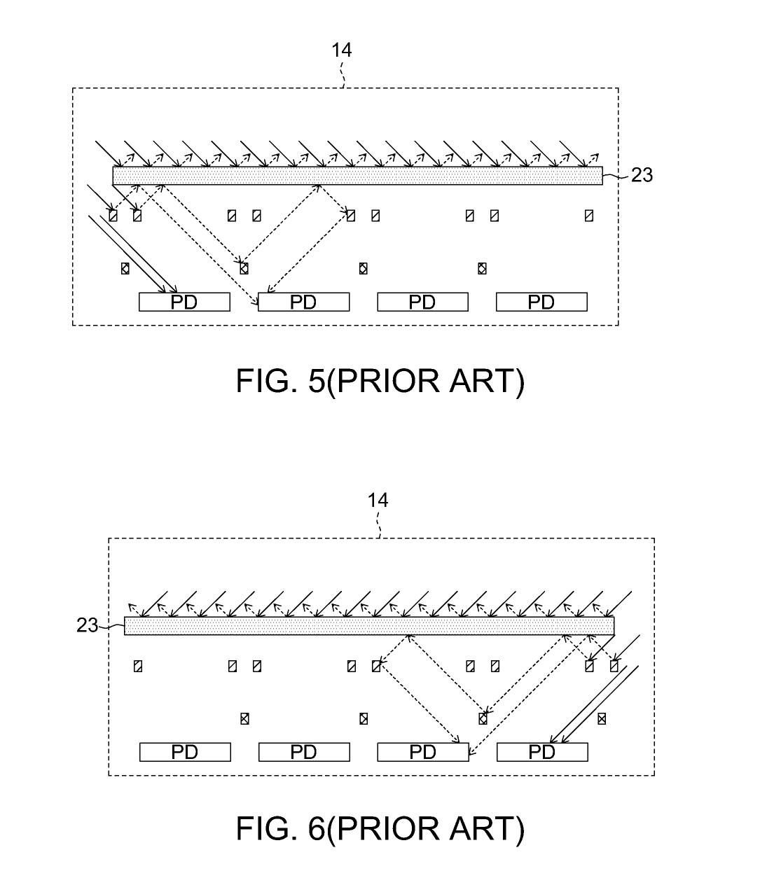

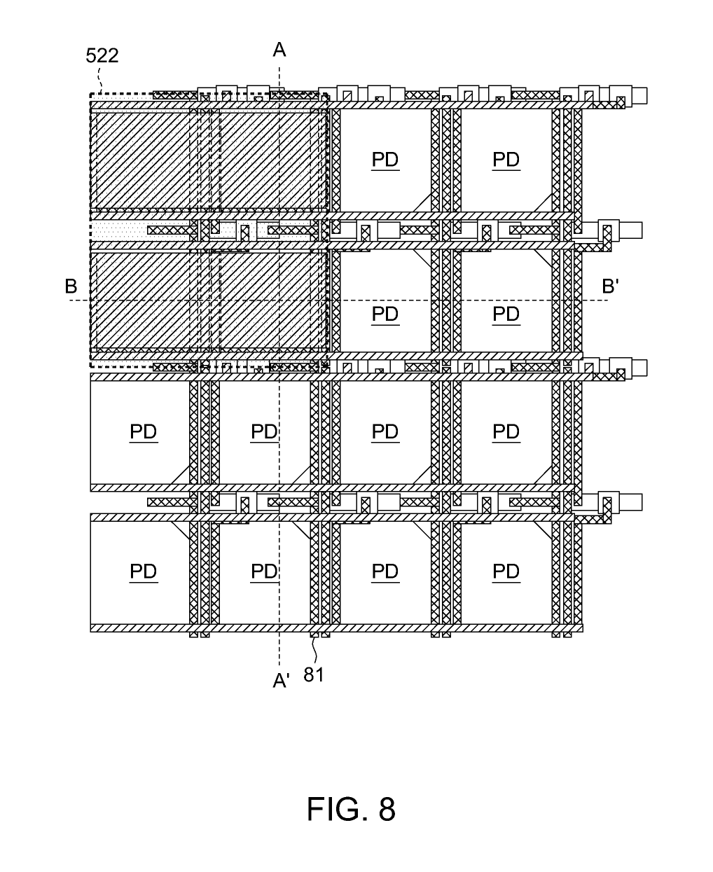

Referring to FIG. 8, a 4×4 pixel array according to a preferred embodiment of the invention is shown. For purpose of simplification, FIG. 8 is exemplified by a 4×4 pixel array which comprises 16 photodiodes PD, and the pixel array of FIG. 2 comprises a 2×2 pixel array 522 located in the dummy black pixel region 52. The photo-sensitive elements PD are realized by such as photodiodes.

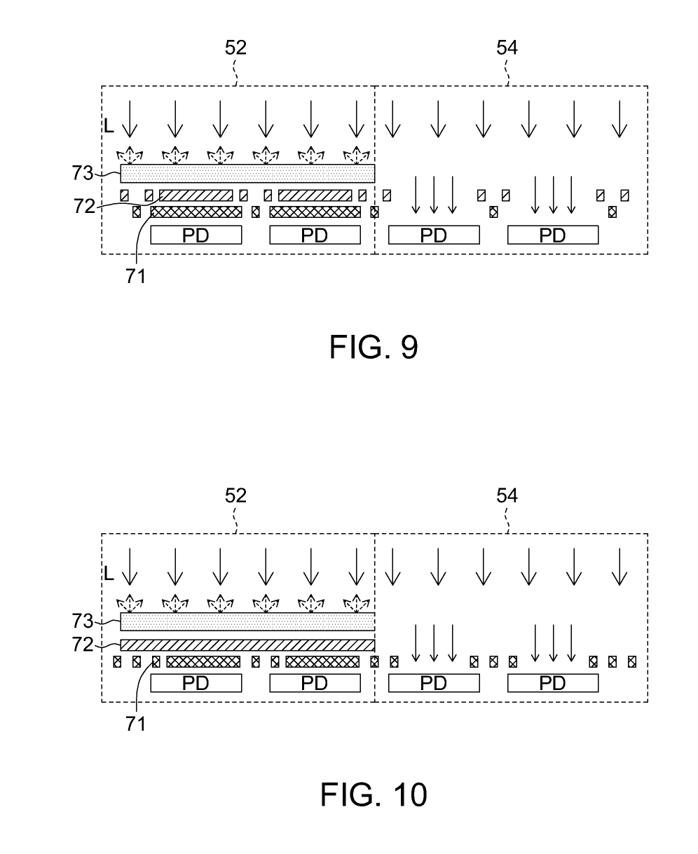

Referring to FIG. 8, FIG. 9 and FIG. 10. FIG. 9 shows a cross-sectional view along the cross-sectional line A-A′ of FIG. 8. FIG. 10 shows a cross-sectional view along the cross-sectional line B-B′ of FIG. 8. The dummy black pixel region 52 comprises a photo-sensitive element PD, a shielding layer 71, a shielding layer 72 and a shielding layer 73. The shielding layer 72 is interposed between the shielding layer 71 and the shielding layer 73. The shielding layer 71 is electrically connected to the power signal line 81 of FIG. 8, and the power signal line 81 is used for transmitting the operating voltage VDD. The shielding layer 71, the shielding layer 72 and the shielding layer 73 cover the photo-sensitive element PD and are used for blocking the incident light L going into the photo-sensitive element PD. The shielding layer 72 can cover one or multiple photo-sensitive elements PD.

Except that the readout black pixel region 53 lacks the shielding layer 71 and the shielding layer 72, the layout structure of the readout black pixel region 53 is similar to that of the dummy black pixel region 52. The readout black pixel region 53 and the black pixel region 14 can be implemented in the same manner. Except that the active pixel region 54 lacks the shielding layers 71, 72 and 73 of the dummy black pixel region 52, the layout structure of the active pixel region 54 is similar to that of the dummy black pixel region 52. The shielding layer 73 is realized by the third metal layer or by the third metal layer and a blue color filter. The shielding layer 71 is realized by such as the first metal layer, and the shielding layer 72 is realized by such as the second metal layer.

When the incident light L is vertically radiated on the pixel array, the shielding layer 73 of the dummy black pixel region 52 reflects the incident light L to avoid the incident light L going into the photodiode PD of the dummy black pixel region 52. Since the active pixel region 54 lacks the shielding layer 73, the incident light L goes into the photodiode PD of the active pixel region 54.

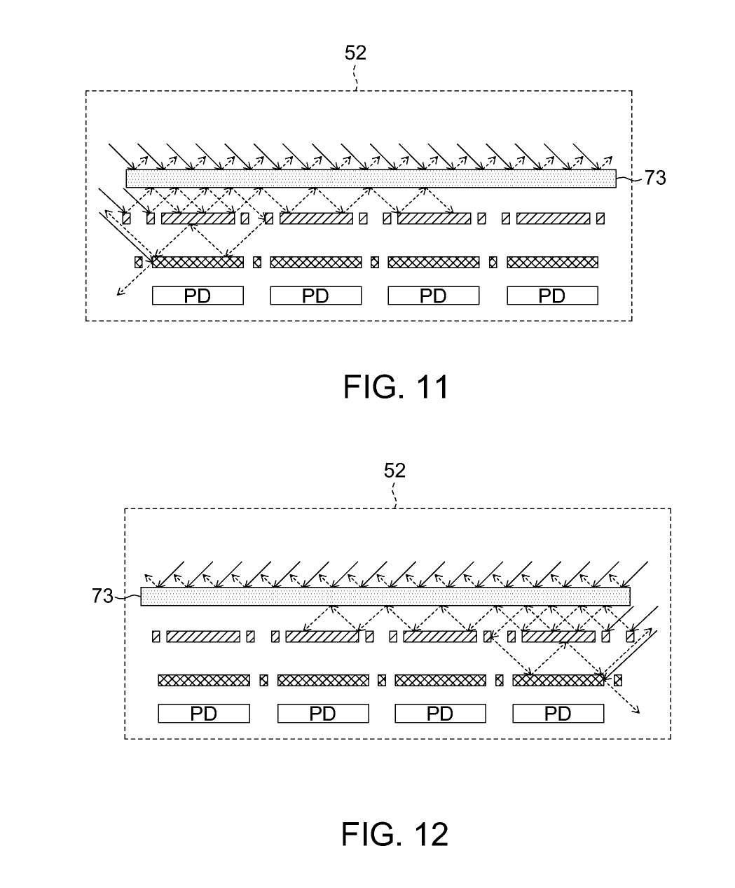

Referring to FIG. 11 and FIG. 12. FIG. 11 shows an incident light being slantedly radiated on the dummy black pixel region along a direction. FIG. 12 shows an incident light being slantedly radiated on the dummy black pixel region along another direction. When the incident light L is slantedly radiated on the dummy the black pixel region 52, the energy of the incident light L decays to 0 due to the shielding layers 71, 72 and 73 to avoid a part of the incident light L going into the photodiode PD of the dummy black pixel region 52.

According to the image sensor disclosed in the above embodiments of the invention, the design of a dummy black pixel region effectively reduces the size of the image sensor.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An image sensor, comprising:
a black pixel region, comprising:
a dummy black pixel region, comprising:
a photo-sensitive element;
a first shielding layer covering the photo-sensitive element;
a second shielding layer covering the photo-sensitive element;
a third shielding layer covering the photo-sensitive element, wherein the second shielding layer is interposed between the first shielding layer and the third shielding layer, and the first shielding layer, the second shielding layer and the third shielding layer are used for blocking the incident light going into the photo-sensitive element;
a readout black pixel region surrounded by the dummy black pixel region; and
an active pixel region adjacent to the black pixel region.

2. The image sensor according to claim 1, wherein the photo-sensitive element is a photodiode.

3. The image sensor according to claim 1, wherein the layout structure of the readout black pixel region is similar to that of the dummy black pixel region except that the readout black pixel region lacks the first shielding layer and the second shielding layer.

4. The image sensor according to claim 1, wherein the second shielding layer further covers another photo-sensitive element.

5. The image sensor according to claim 1, wherein the first shielding layer is a first metal layer.

6. The image sensor according to claim 1, wherein the second shielding layer is a second metal layer.

7. The image sensor according to claim 1, wherein the third shielding layer is a third metal layer.

8. The image sensor according to claim 1, wherein the third shielding layer is realized by a third metal layer and a blue color filter.
